(19) United States
(12) Patent Application Publication
(10) Pub. No.: US 2026/0065842 A1
(43) Pub. Date: Mar. 5, 2026

(54) DISPLAY PANEL AND DISPLAY DEVICE

(71) Applicant: Xiamen Tianma Display Technology Co., Ltd., Xiamen (CN)

(72) Inventor: Qingjun LAI, Xiamen (CN)

(21) Appl. No.: 19/191,805

(22) Filed: Apr. 28, 2025

(30) Foreign Application Priority Data
Sep. 3, 2024 (CN) 202411230982.3

(51) Int. Cl. G09G 3/32; G11C 19/28

(52) U.S. Cl. CPC G09G 3/32; G11C 19/287; G09G 2300/0819; G09G 2300/0842; G09G 2300/0861; G09G 2310/0221; G09G 2310/0286; G09G 2310/04; G09G 2320/0223; G09G 2340/0435

(57) ABSTRACT

Display panel and display device are provided. The display panel includes a plurality of shift registers in cascade, for generating primary scan signals, primary scan signals output by adjacent shift registers overlapping; a plurality of gating circuits, electrically connected to the plurality of shift registers in a one-to-one correspondence, for generating scan signals, a frequency of a scan signal of the scan signals being less than or equal to a frequency of a primary scan signal of the primary scan signals; control signal lines, including a first control signal line; and a plurality of shift register areas, each of the plurality of shift register areas comprising at least one shift register.

### CROSS-REFERENCE TO RELATED APPLICATION

This application claims priority of Chinese Patent Application No. 2024112309823, filed on Sep. 3, 2024, the entire contents of which are hereby incorporated by reference.

### FIELD OF THE DISCLOSURE

The present disclosure generally relates to the field of display technology and, more particularly, relates to a display panel and a display device.

### BACKGROUND

With the development of display and hardware technologies, display panels are becoming increasingly larger. To make full use of a display panel, a split-screen display function is proposed, which allows different operation interfaces to be displayed simultaneously in different display areas on the display panel, such as showing news in a part of areas while playing a video in another part of areas or displaying different game perspectives in different areas. Each display partition can be arranged with a different refresh frequency. However, ensuring a display quality of display partitions has become an urgent issue to address.

### BRIEF SUMMARY OF THE DISCLOSURE

One aspect of the present disclosure provides a display panel. The display panel includes a plurality of shift registers in cascade, for generating primary scan signals, primary scan signals output by adjacent shift registers overlapping; a plurality of gating circuits, electrically connected to the plurality of shift registers in a one-to-one correspondence, for generating scan signals, a frequency of a scan signal of the scan signals being less than or equal to a frequency of a primary scan signal of the primary scan signals; control signal lines, including a first control signal line; a plurality of shift register areas, each of the plurality of shift register areas comprising at least one shift register, the plurality of shift register areas comprising an i-th area, an (i+1)-th area and an (i+j)-th area, the (i+1)-th area being located between the i-th area and the (i+j)-th area, where i is a positive integer, and j is a positive integer greater than 1; the i-th area and the (i+j)-th area further including a gating circuit of the plurality of gating circuits, gating circuits in the i-th area and the (i+j)-th area being electrically connected to the first control signal line, and in response to a first signal on the first control signal line, frequencies of the scan signals of the gating circuits in the i-th area and the (i+j)-th area being controlled; and the (i+1)-th area being not electrically connected to the first control signal line.

Another aspect of the present disclosure provides a display device including a display panel. The display panel includes a plurality of shift registers in cascade, for generating primary scan signals, primary scan signals output by adjacent shift registers overlapping; a plurality of gating circuits, electrically connected to the plurality of shift registers in a one-to-one correspondence, for generating scan signals, a frequency of a scan signal of the scan signals being less than or equal to a frequency of a primary scan signal of the primary scan signals; control signal lines, including a first control signal line; a plurality of shift register areas, each of the plurality of shift register areas comprising at least one shift register, the plurality of shift register areas comprising an i-th area, an (i+1)-th area and an (i+j)-th area, the (i+1)-th area being located between the i-th area and the (i+j)-th area, where i is a positive integer, and j is a positive integer greater than 1; the i-th area and the (i+j)-th area further including a gating circuit of the plurality of gating circuits, gating circuits in the i-th area and the (i+j)-th area being electrically connected to the first control signal line, and in response to a first signal on the first control signal line, frequencies of the scan signals of the gating circuits in the i-th area and the (i+j)-th area being controlled; and the (i+1)-th area being not electrically connected to the first control signal line.

Other aspects of the present disclosure can be understood by a person skilled in the art in light of the description, the claims, and accompanying drawings of the present disclosure.

### BRIEF DESCRIPTION OF THE DRAWINGS

FIG. 1 illustrates a circuit diagram of a display panel;

FIG. 2 illustrates a driving timing diagram of the display panel shown in FIG. 1;

FIG. 3 illustrates a circuit diagram of a display panel consistent with various embodiments of the present disclosure;

FIG. 4 illustrates a circuit diagram of another display panel consistent with various embodiments of the present disclosure;

FIG. 5 illustrates a circuit diagram of another display panel consistent with various embodiments of the present disclosure;

FIG. 6 illustrates a driving timing diagram of a display panel consistent with various embodiments of the present disclosure;

FIG. 7 illustrates a driving timing diagram of another display panel consistent with various embodiments of the present disclosure;

FIG. 8 illustrates a driving timing diagram of another display panel consistent with various embodiments of the present disclosure;

FIG. 9 illustrates a driving timing diagram of another display panel consistent with various embodiments of the present disclosure;

FIG. 10 illustrates a driving timing diagram of another display panel consistent with various embodiments of the present disclosure;

FIG. 11 illustrates a driving timing diagram of another display panel consistent with various embodiments of the present disclosure;

FIG. 12 illustrates a circuit diagram of another display panel consistent with various embodiments of the present disclosure;

FIG. 13 illustrates a driving timing diagram of another display panel consistent with various embodiments of the present disclosure;

FIG. 14 illustrates a circuit diagram of another display panel consistent with various embodiments of the present disclosure;

FIG. 15 illustrates a driving timing diagram of another display panel consistent with various embodiments of the present disclosure;

FIG. 16 illustrates a circuit diagram of another display panel consistent with various embodiments of the present disclosure;

FIG. 17 illustrates a driving timing diagram of another display panel consistent with various embodiments of the present disclosure;

FIG. 18 illustrates a schematic diagram showing varying refresh frequencies across a plurality of shift register areas consistent with various embodiments of the present disclosure;

FIG. 19 illustrates a schematic diagram showing another type of varying refresh frequencies across a plurality of shift register areas consistent with various embodiments of the present disclosure;

FIG. 20 illustrates a planar view of a display panel consistent with various embodiments of the present disclosure;

FIG. 21 illustrates a structural view of a 7T1C pixel circuit consistent with various embodiments of the present disclosure;

FIG. 22 illustrates a circuit diagram of another display panel consistent with various embodiments of the present disclosure; and

FIG. 23 illustrates a schematic diagram of a display device consistent with various embodiments of the present disclosure.

### DETAILED DESCRIPTION

The present disclosure will be described in further detail below in conjunction with the accompanying drawings and embodiments. The specific embodiments described herein are intended to only explain rather than to limit the present disclosure. It should also be noted that, for ease of description, only the parts related to the present disclosure are shown in the accompanying drawings, rather than all structures. Various modifications and variations can be made to the present disclosure without departing from the spirit or scope of the present disclosure, which will be apparent to a person skilled in the art. Therefore, the present disclosure is intended to cover the modifications and variations of the present disclosure that fall within the scope of corresponding claims (technical solutions claimed for protection) and equivalents thereof. It should be noted that implementation methods provided in the embodiments of the present disclosure can be combined with each other, provided there is no contradiction.

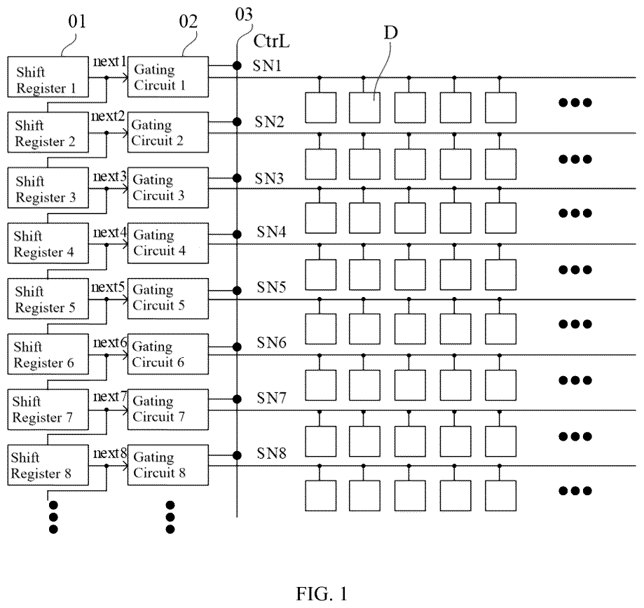

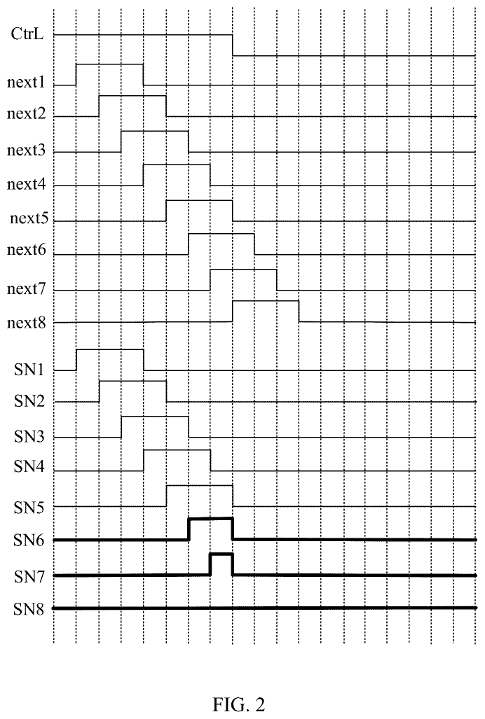

FIG. 1 illustrates a circuit diagram of a display panel. FIG. 2 illustrates a driving timing diagram of the display panel shown in FIG. 1. As shown in FIG. 1, a multi-frequency display (MFD) product generally includes a plurality of shift registers 01 in cascade, a plurality of gating circuits 02 and a control signal line 03. Taking a circuit connection of eight shift registers 01, eight gating circuits 02 and one control signal line 03 in FIG. 1 as an example, and referring to FIG. 2, when the MFD product displays one frame, the control signal line 03 provides a frequency-cutting signal CtrL, and the first to eighth shift registers 01 respectively generate eight primary scan signals, labeled next1 to next8 with the primary scan signals output by adjacent shift registers 01 overlapping. For example, a first primary scan signal next1 overlaps a second primary scan signal next2, the second primary scan signal next2 overlaps a third primary scan signal next3, the third primary scan signal next3 overlaps a fourth primary scan signal next4, and so on. The first to eighth gating circuits 02 generate eight scan signals SN1 to SN8 respectively, in response to the frequency-cutting signal CtrL. The frequency-cutting signal CtrL controls whether a primary scan signal is output as a scan signal.

In FIG. 2, in one embodiment, a scan signal is obtained by performing an AND operation on the frequency-cutting signal CtrL and a primary scan signal and an enable level of the frequency-cutting signal CtrL provided by the control signal line 03 is a high level. In other embodiments, a scan signal can also be generated by other algorithms or methods, by controlling a primary scan signal by the frequency-cutting signal CtrL. In other words, the frequency-cutting signal CtrL determines whether the primary scan signal is output as the scan signal. When the primary scan signal is output as the scan signal, the primary scan signal is controlled to have a same timing and waveform as the scan signal. When the primary scan signal is not output as the scan signal, the scan signal can maintain a fixed voltage value, thereby reducing a frequency of the scan signal. In other embodiments, the enable level of the frequency-cutting signal CtrL can also be at a low level.

Since primary scan signals output by adjacent level shift register s01 overlap, during a split-screen control, the control signal line 03 provides the frequency-cutting signal CtrL to control primary scan signals (e.g., next1 to next8). A low level of the frequency-cutting signal CtrL overlaps a 6th primary scan signal next6, a 7th primary scan signal next7, and an 8th primary scan signal next8, resulting in partial cutoffs of the 6th scan signal SN6 and the 7th scan signal SN7, and a complete cutoff of the 8th scan signal SN8. Therefore, the 6th scan signal SN6, the 7th scan signal SN7, and the 8th scan signal SN8 become abnormal, ultimately affecting a normal display of the display panel. A cutoff of a scan signal means that the scan signal, which should have been outputted has a same pulse width as the primary scan signal, instead has a pulse width smaller than the pulse width of the primary scan signal due to a low-level overlap of the primary scan signal and the frequency-cutting signal CtrL.

Since the primary scan signals output by a plurality of shift registers 10 overlap, the control signal line 03 is used to control all the gating circuits 20. When the output frequency-cutting signal CtrL is at a low level, the frequency-cutting signal CtrL inevitably overlaps continuously overlapping primary scan signals. The frequency-cutting signal CtrL generates a voltage jump, which causes a voltage drop from a high level to a low level at a falling edge of the frequency-cutting signal CtrL), at points where part of the scan signals overlap, resulting in cutoffs of the part of scan signals near the voltage jump.

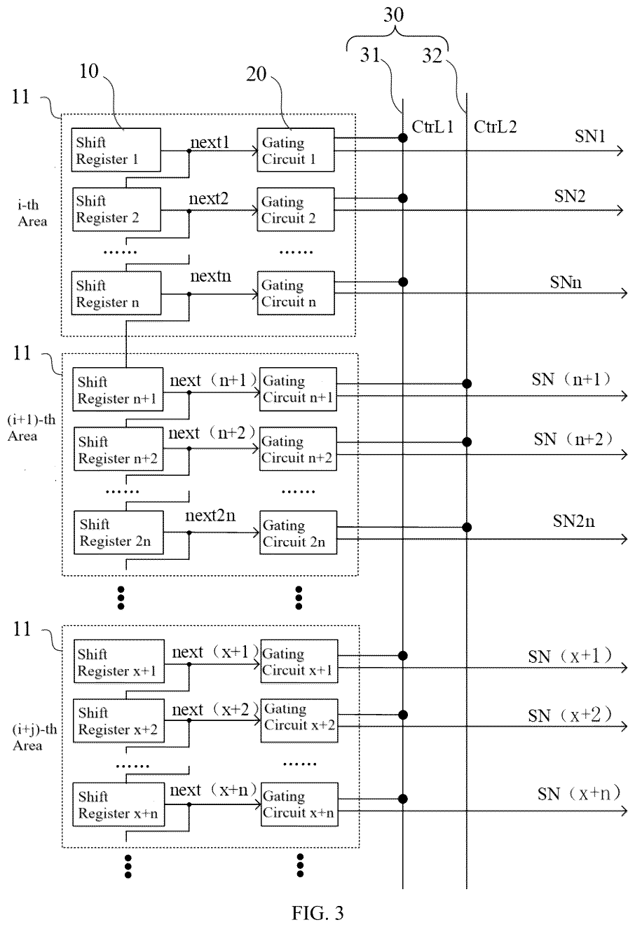

FIG. 3 illustrates a circuit diagram of a display panel consistent with various embodiments of the present disclosure. As shown in FIG. 3, the display panel includes a plurality of shift registers 01 in cascade, a plurality of gating circuits 20, a control signal line 30 and a plurality of shift register areas 11. A shift register of the plurality of shift registers 01 in cascade is used to generate a primary scan signal. Primary scan signals output by adjacent shift registers 10 overlap. A gating circuit 20 is electrically connected to a shift register 10, and the gating circuit 20 is used to generate a scan signal, and a frequency of a scan signal is less than or equal to a frequency of a primary scan signal. The control signal line 30 includes a first control signal line 31. Each of the plurality of shift register areas 11 includes at least one shift register 10. In one embodiment, the plurality of shift registers 01 in cascade is in the same driving circuit. The plurality of shift registers 01 in cascade is respectively arranged in the plurality of shift register areas 11. The plurality of shift register areas 11 includes an i-th area, an (i+1)-th area, and an (i+j)-th area, and the (i+1)-th area is between the i-th area and the (i+j)-th area. The i-th area and the (i+j)-th area also include gating circuits 20. The gating circuits 20 in the i-th area and the (i+j)-th area are electrically connected to the first control signal line 31. In response to a first signal CtrL1 on the first control signal line 31, frequencies of scan signals of the gating circuits 20 in the i-th area and the (i+j)-th area are controlled. The gating circuits in the (i+1)-th area are not electrically connected to the first control signal line 31, where i is a positive integer and j is a positive integer greater than 1.

Exemplarily, referring to FIG. 3, a first shift register 10 (illustrated as shift register 1 in FIG. 3) generates a first primary scan signal next1, a second shift register 10 (illustrated as shift register 2 in FIG. 3) generates the second primary scan signal next2 . . . , and a n-th shift register 10 (illustrated as shift register n in FIG. 3) generates a n-th primary scan signal nextn. A (n+1)-th shift register 10 (illustrated as shift register (n+1) in FIG. 3) generates a (n+1)-th primary scan signal next (n+1), and a (n+2)-th shift register 10 (illustrated as shift register (n+2) in FIG. 3) generates zn+2th primary scan signal next (n+2). The (2n)-th shift register 10 (illustrated as shift register 2n in FIG. 3) generates a 2nth primary scan signal next2n. A (x+1)-th shift register 10 (illustrated as shift register (x+1) in FIG. 3) generates a (x+1)-th primary scan signal next (x+1). A (x+2)-th shift register 10 (illustrated as shift register (x+2) in FIG. 3) generates a (x+2)-th primary scan signal next (x+2). A (x+n)-th shift register 10 (shown as shift register (x+n) in FIG. 3) generates a (x+n)-th primary scan signal next (x+n). n≥2, x>2n, and x and n are positive integers. It should be noted that the first shift register 10 in one embodiment is explained by taking i=1 as an example. When i is a positive integer greater than 1, as shown in FIG. 3, the display panel further includes additional shift registers 10, preceding the first shift register 10.

Exemplarily, referring to FIG. 3, the first gating circuit 20 (shown as gating circuit 1 in FIG. 3) generates the first scan signal SN1, and the second gating circuit 20 (shown as gating circuit 2 in FIG. 3) generates a second scan signal SN2. An n-th gating circuit 20 (shown as gating circuit n in FIG. 3) generates a n-th scan signal SNn. An (n+1)-th gating circuit 20 (shown as gating circuit (n+1) in FIG. 3) generates an (n+1)-th scan signal SN (n+1). An (n+2)-th gating circuit 20 (shown as gating circuit (n+2) in FIG. 3) generates an (n+2)-th scan signal SN (n+2). An (2n)-th gating circuit 20 (illustrated as the gating circuit 2n in FIG. 3) generates the (2n)-th scan signal SN2n. A (x+1)-th gating circuit 20 (shown as gating circuit x+1 in FIG. 3) generates a (x+1)-th scan signal SN (x+1). A (x+2)-th gating circuit 20 (shown as gating circuit (x+2) in FIG. 3) generates a (x+2)-th scan signal SN (x+2). A (x+n)-th gating circuit 20 (illustrated as gating circuit (x+n) in FIG. 3) generates a (x+n)-th scan signal SN (x+1).

Number of gating circuits 20 may be same as or different from number of shift registers 10. For example, referring to FIG. 3, the number of gating circuits 20 is same as the number of shift registers 10. The gating circuits 20 are electrically connected to the shift registers 10 in a one-to-one correspondence. A shift register 10 and a gating circuit 20 are connected to form a group. Each shift register area 11 includes at least one group including a shift register 10 and a correspondingly connected gating circuit 20. For example, the first gating circuit 20 is electrically connected to the first shift register 10. The second gating circuit 20 is electrically connected to the second shift register 10.

A gating circuit 20 controls a transmission path of a primary scan signal output by a shift register 10 electrically connected to the gating circuit 20. For example, when the gating circuit 20 is turned on, the primary scan signal output by the shift register 10 can pass through the gating circuit 20, ensuring that a scan signal output by the gating circuit 20 is identical to a scan signal output by the shift register 10, and the primary scan signal is output as a scan signal to a pixel circuit (not shown in FIG. 3) to control an operation of the pixel circuit. When the gating circuit 20 is turned off, and the primary scan signal output by the shift register 10 cannot pass through the gating circuit 20. Therefore, a scan signal output by the gating circuit 20 is different from a scan signal output by the shift register 10, and the primary scan signal is not output to a pixel circuit as a scan signal. The pixel circuit is not refreshed, which reduces the frequency of the scan signal and a refresh frequency of the screen in a display partition.

For example, when a gateing circuit 20 in the i-th area is turned on, the first preliminary scan signal next1 is same as the first scan signal SN1, and the second preliminary scan signal next2 is same as the second scan signal SN2. The n-th primary scan signal nextn is same as the n-th scan signal SNn. A pixel circuit connected to the i-th area is refreshed. The i-th area implements a high-frequency refresh. When the gating circuits 20 in the (i+j)-th area are turned off, the (x+1)-th primary scan signal next (x+1) is different from the (x+1)-th scan signal SN (x+1), and the (x+2)-th primary scan signal next (x+2) is different from the (x+2)-th scan signal SN (x+2). The (x+n)-th primary scan signal next (x+n) is different from the (x+n)-th scan signal SN (x+n). A pixel circuit connected to the (i+j)-th area is not refreshed. Therefore, a refresh frequency of the pixel circuit connected to the (i+j)-th area is reduced, and a refresh frequency of the display area controlled by the (i+j)-th area is reduced, and the (i+j)-th area implements a low-frequency refresh.

The first control signal line 31 is electrically connected to gating circuits 20 in both the i-th area and the (i+j)-th area. The first control signal line 31 is not electrically connected to the shift register 10 in the (i+1)-th area. The first control signal line 31 cannot control a frequency of the primary scan signal output by the shift register 10 in the (i+1)-th area to drive a pixel circuit. In one embodiment, gating circuits 20 may not be arranged in the (i+1)-th area. In another embodiment, gating circuits 20 are arranged in the (i+1)-th area, and the gating circuits 20 in the (i+1)-th area are not electrically connected to the first control signal line 31 but may be connected to other signal lines.

In one embodiment, the first control signal line 31 is electrically connected to gating circuits 20 in both the i-th area and (i+j)-th area. The (i+1)-th area is also arranged between the i-th area and the (i+j)-th area. The first control signal line 31 is not electrically connected to the (i+1)-th area. The first control signal line 31 is electrically connected to at least two non-adjacent circuit areas. When the first signal CtrL1 activates the gating circuits 20 in the i-th area and deactivates the gating circuits 20 in the (i+j)-th area, or when the first signal CtrL1 deactivates the gating circuits 20 in the i-th area and activates the gating circuits 20 in the (i+j)-th area, a voltage jump of the first signal CtrL1 can occur during a driving period corresponding to the (i+1)-th area, but not occur during driving periods corresponding to the i-th area and the (i+j)-th area, and will not cut off scan signals in the i-th area and the (i+j)-th area. Therefore, Abnormalities in the scan signals of the i-th area and the (i+j)-th area are avoided, thereby improving the display effect of the display panel. The embodiment can not only not only enable partitioned frequency control of the display panel but also prevents display abnormalities in each partition, thereby enhancing the display effect and user experience.

Partition frequency control refers to a management of frequencies for different display partitions. Display partitions are different display areas in the display area. Corresponding to different display partitions, different shift registers are arranged to control a refresh frequency of a pixel circuit in the display partition, thereby managing a refresh frequency of images in the display partition. Usually, the shift registers have a same number as the display partitions, and the shift registers are arranged one-to-one with the display partitions. The shift registers may include, for example, the i-th area, the (i+1)-th area, and the (i+j)-th area.

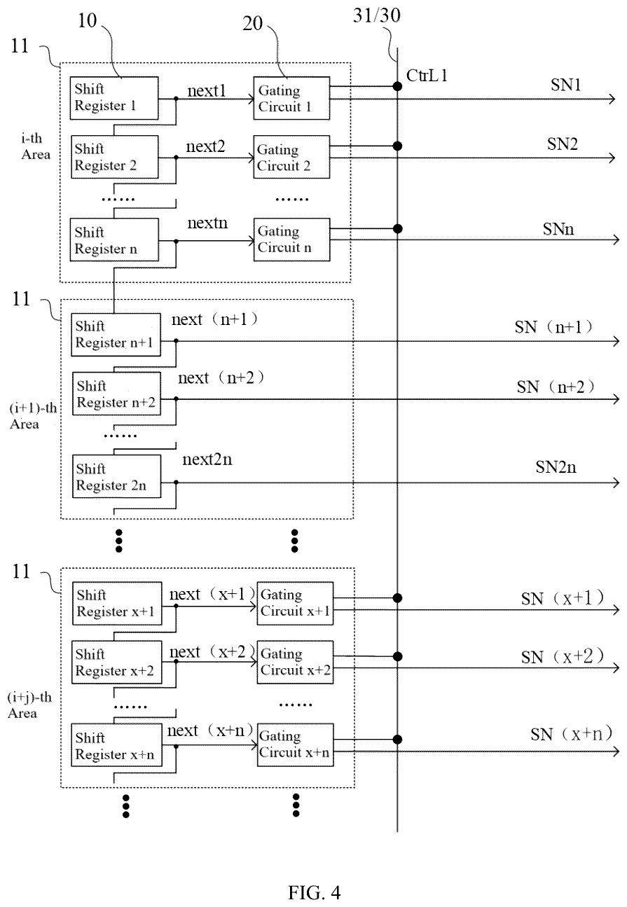

FIG. 4 illustrates a circuit diagram of another display panel consistent with various embodiments of the present disclosure. As shown in FIG. 4, no gating circuits 20 is arranged in the (i+1)-th area, and primary scan signals output by the (n+1)-th to (2n)-th shift registers 10 in the (i+1)-th area are directly output as scan signals to a pixel circuit. In the above application scenario, a refresh frequency of a pixel circuit connected to the (i+1)-th area cannot be changed.

Furthermore, frequencies of scan signals of the gating circuits 20 in the i-th area and the (i+j)-th area can be controlled by adjusting the first signal CtrL1. When a frequency of a scan signal of each gating circuit 20 in the display panel matches a frequency of a primary scan signal, a refresh frequency of each area in the display panel becomes uniform, and the display panel performs a normal display without area division and frequency division. When the frequencies of the scan signals of the gating circuits 20 in the i-th area of the display panel are equal to the frequencies of the primary scan signals, and frequencies of scan signals of the gating circuits 20 in the (i+j)-th area are less than the frequencies of the primary scan signals, the display panel can achieve different refresh frequencies in the i-th area and the (i+j)-th area, thereby achieving a normal display across the display panel with different areas and frequencies.

It should be noted that in FIGS. 3 and 4, i≥2, and the display panel also includes a (i−1)-th area, a (i−2)-th area, and so on preceding the i-th area, which are not shown herein.

In a scenario where a split-screen display is required, for example, an upper half of a screen may be used for gaming, which requires a high refresh frequency, while a lower half of the screen may be used for reading text, which requires a low refresh frequency. Typically, there are not too many split screens. In other embodiments, to accommodate a user's adjustment of a size of the upper half screen or the lower half screen during use, number of display partitions is usually large, potentially reaching hundreds or thousands of display partitions. The more display partitions there are, on the one hand, the smaller a granularity of the display partitions, and on the other hand, the more options a user has or the greater freedom of adjustment when the user adjusts the size of the upper half screen or the lower half screen, which provides a higher user experience. Number of display partitions in the display panel is not limited herein.

It should be noted that the display panel also includes a driving circuit, which includes a plurality of shift registers 10. An output end of a gating circuit 20 is electrically connected to a pixel circuit for providing a driving signal to the pixel circuit. The pixel circuit can be a circuit structure such as 2T1C, 4T1C, 7T1C, 7T2C, 8T1C, 8T2C, or the like, which is not specifically limited herein. The pixel circuit includes a plurality of thin film transistors (TFTs), storage capacitors, metal wiring and other structures. One electrode of a thin film transistor of the plurality of thin film transistors is electrically connected to one electrode of a light-emitting element to provide a driving voltage to the light-emitting element to drive the light-emitting element to emit light.

Based on the above embodiment, the issue of scan signal cutoff can be mitigated by appropriately controlling a length of the signal. Some specific embodiments are detailed below for further explanation.

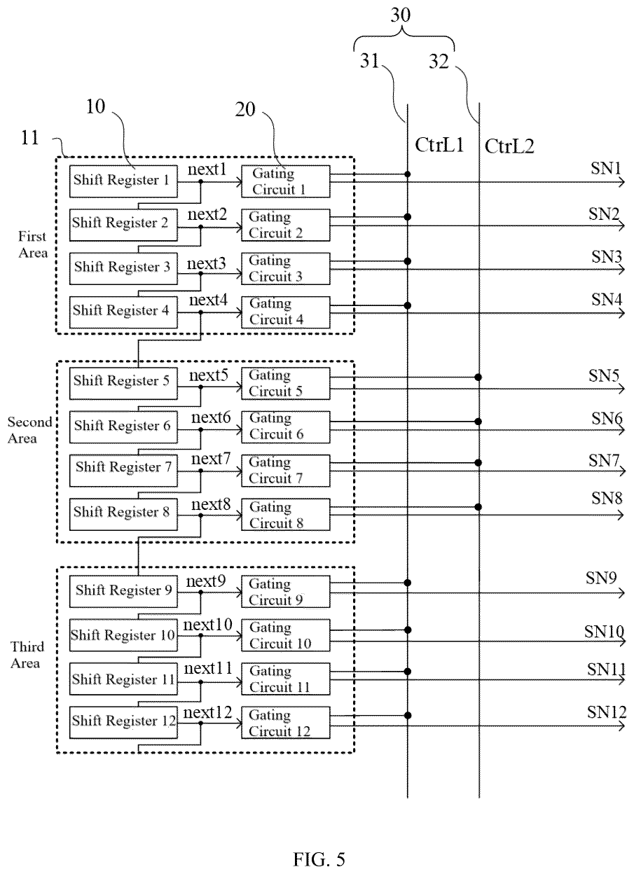

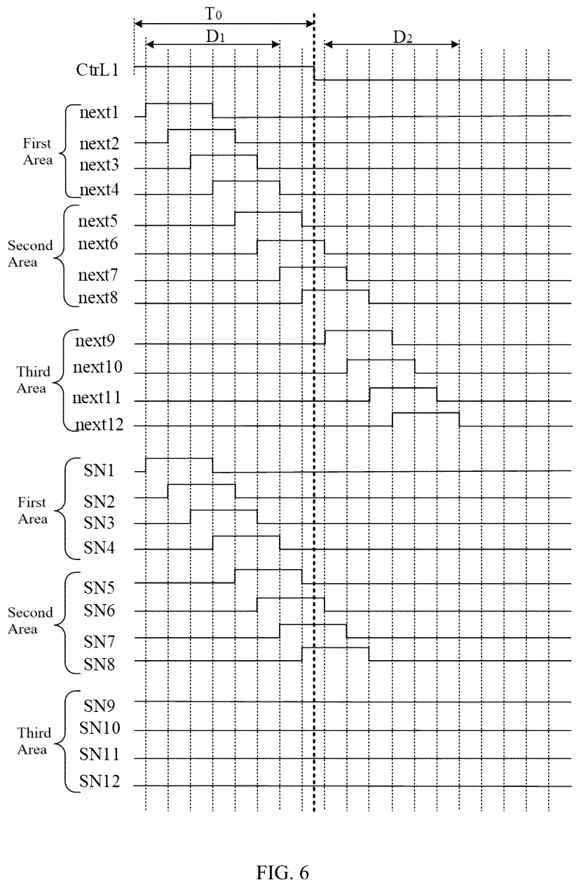

FIG. 5 illustrates a circuit diagram of another display panel consistent with various embodiments of the present disclosure. FIG. 6 illustrates a driving timing diagram of the display panel provided in FIG. 5. Referring to FIG. 5 and FIG. 6, i=1, j=2 is used as an example. A duration occupied by a plurality of primary scan signals in the i-th area is a first duration D1, and a duration occupied by a plurality of primary scan signals in the (i+j)-th area is a second duration D2. A width TO of an enable level of the first signal CtrL1 is greater than the first duration D1 and/or the second duration D2. A duration occupied by a plurality of primary scan signals in a specific shift register area refers to a duration between a start of a first primary scan signal and an end of a last primary scan signal in the specific shift register area.

Referring to FIG. 5, taking i=1, j=2 as an example, FIG. 5 illustrates three adjacent shift register areas 11: a first area, a second area, and a third area. Each shift register area includes four shift registers 10 and four gating circuits 20. In the first area, four shift registers (labeled shift register 1, shift register 2, shift register 3, and shift register 4 in FIG. 5) generate primary scan signals, namely, the first primary scan signal next1, the second primary scan signal next2, the third primary scan signal next3, and the fourth primary scan signal next4. The scan signals generated by the four gating circuits 20 in the first area (shown as gating circuit 1, gating circuit 2, gating circuit 3, and gating circuit 4 in FIG. 5) in response to the first signal CtrL1 are the first scan signal SN1, the second scan signal SN2, the third scan signal SN3, and the fourth scan signal SN4. The four shift registers 10 in the third area (shown as shift register 9, shift register 10, shift register 11, and shift register 12 in FIG. 5) respectively generate primary scan signals, namely, a ninth primary scan signal next9, a tenth primary scan signal next10, an eleventh primary scan signal next11, and a twelfth primary scan signal next12. The scan signals generated by the four gating circuits 20 in the third area (labeled gating circuit 9, gating circuit 10, gating circuit 11, and gating circuit 12 in FIG. 5) in response to the first signal CtrL1 are the nineth scan signal SN9, the tenth scan signal SN10, the eleventh scan signal SN11, and the 12th scan signal SN12. In the second area, the four shift registers 10 (labeled shift register 5, shift register 6, shift register 7, shift register 8 in FIG. 5) respectively generate primary scan signals of the fifth primary scan signal next5, the sixth primary scan signal next6, the seventh primary scan signal next7, and the eighth primary scan signal next8. The scan signals generated by the four gating circuits 20 in the second area (labeled gating circuit 5, gating circuit 6, gating circuit 7, and gating circuit 8 in FIG. 5) are the fifth scan signal SN5, the sixth scan signal SN6, the seventh scan signal SN7, and the eighth scan signal SN8. The fifth scan signal SN5 to the eighth scan signal SN8 are not controlled by the first signal CtrL1.

As shown in FIG. 6, the enable level of the first signal CtrL1 is a high level. In one frame of the display panel, by controlling the width TO of the enable level of the first signal CtrL1 to be greater than the first duration D1, the enable level of the first signal CtrL1 can completely cover the primary scan signal of the i-th area (e.g., i=1), thereby preventing a voltage jump of the first signal CtrL1 from occurring during a driving period corresponding to the i-th area, and avoiding a cutoff of the scan signal in the i-th area.

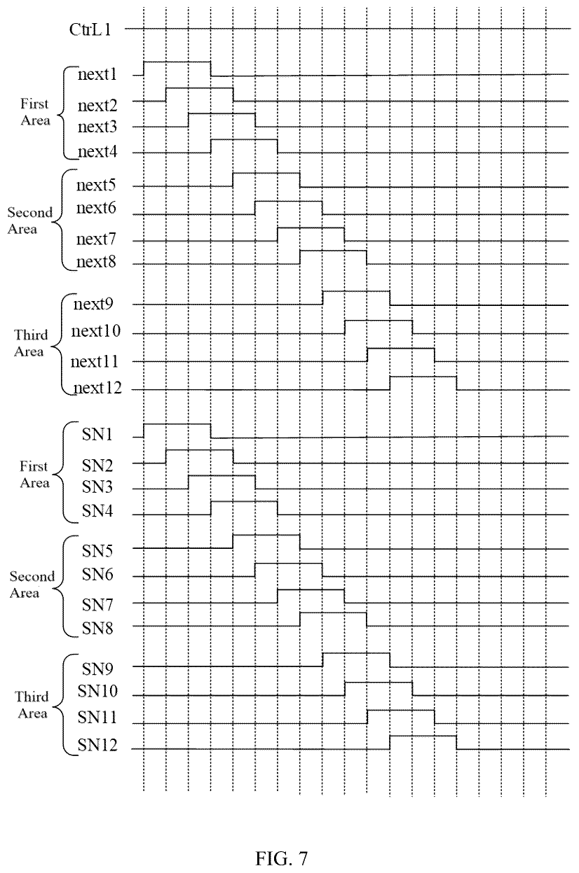

One embodiment illustrates an area frequency display of the display panel. Referring to FIG. 5 and FIG. 6, in one frame, the enable level of the first signal CtrL1 completely covers a primary scan signal in the first area. The enable level of the first signal CtrL1 activates gating circuits 20 in the first area, resulting in the frequencies of the primary scan signals being equal to frequencies of scan signals in the first area. A non-enable level of the first signal CtrL1 completely covers a primary scan signal in the third area. The non-enable level of the first signal CtrL1 deactivates the gating circuits 20 in the third area, causing the frequencies of the primary scan signals in the third area to be less than frequencies of scan signals. FIG. 7 illustrates a driving timing diagram of another display panel consistent with various embodiments of the present disclosure. Referring to FIGS. 5 and 7, in another frame, the first signal CtrL1 is at a high level. The enable level of the first signal CtrL1 completely covers a primary scan signal in the first area. The enable level of the first signal CtrL1 activates the gating circuits 20 in the first area, and the frequencies of the primary scan signals are equal to frequencies of scan signals in the first area. The enable level of the first signal CtrL1 completely covers the primary scan signal in the third area. The enable level of the first signal CtrL1 activates the gating circuits 20 in the third area, and the frequencies of the primary scan signals are equal to frequencies of scan signals in the third area. In conjunction with FIG. 5, FIG. 6, and FIG. 7, in general, the frequencies of the scan signals in the first area is greater than the frequencies of the scan signals in the third area. A refresh frequency of a pixel circuit driven by the first area is greater than a refresh frequency of a pixel circuit driven by the third area. For example, the refresh frequency of the pixel circuit driven by the first area is 120 Hz, and the refresh frequency of the pixel circuit driven by the third area is 60 Hz.

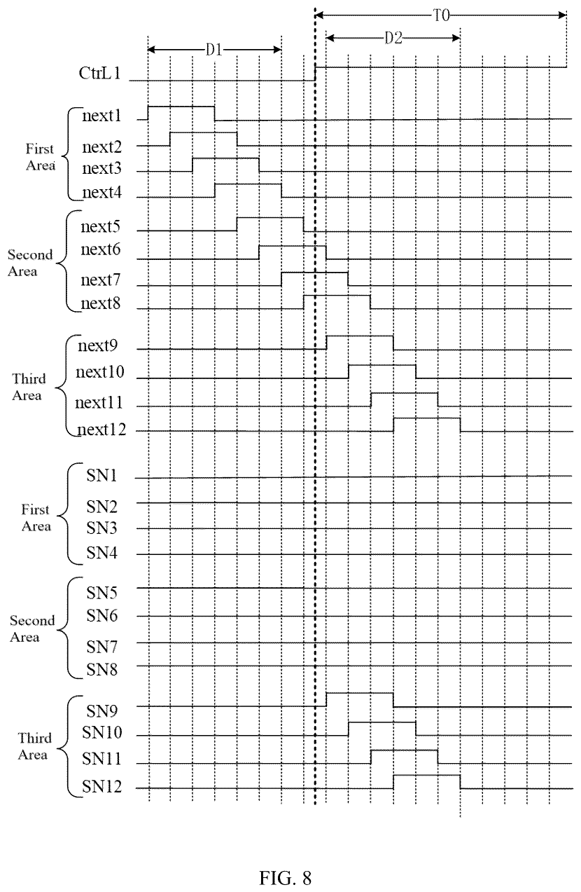

FIG. 8 illustrates a driving timing diagram of another display panel consistent with various embodiments of the present disclosure. Referring to FIG. 8, by controlling the width TO of the enable level of the first signal CtrL1 to be greater than the second duration D2, the enable level of the first signal CtrL1 completely covers the primary scan signal of the (i+j)-th area (e.g., i=1, j=2), thereby preventing a voltage jump of the first signal CtrL1 from occurring during a driving period corresponding to the (i+j)-th area, and avoiding a cutoff of the scan signal in the (i+j)-th area.

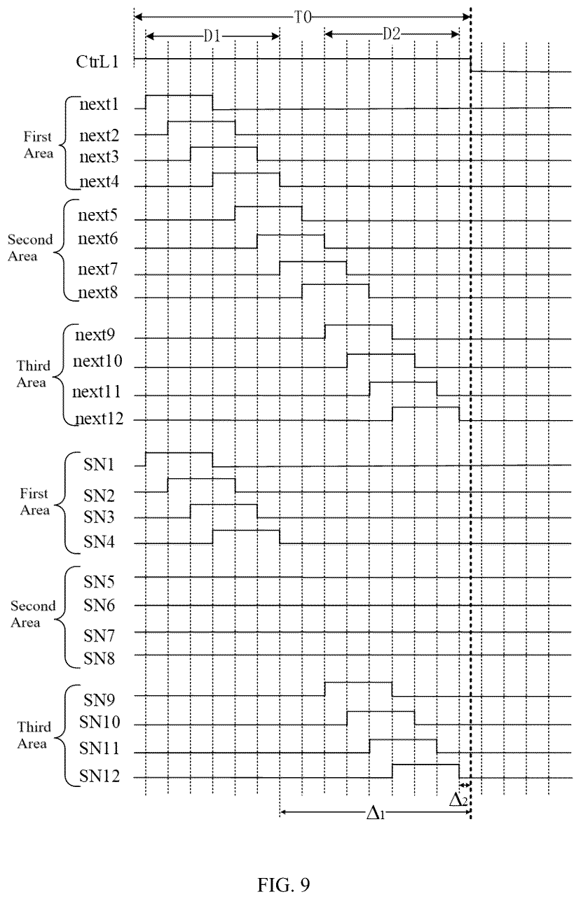

FIG. 9 illustrates a driving timing diagram of another display panel consistent with various embodiments of the present disclosure. Referring to FIG. 9, the width TO of the enable level of the first signal CtrL1 is greater than the first duration D1 and the second duration D2, so as to avoid a voltage jump of the first signal CtrL1 from occurring during the driving period corresponding to the i-th area or the (i+j)-th area, thereby preventing a cutoff of the scan signal in the i-th area or the (i+j)-th area.

Exemplarily, referring to FIG. 9, when T0>D1, T0>D2, the enable level of the first signal CtrL1 completely covers driving time periods corresponding to the first area and the third area, and the first area and the third area can each generate eight normal output scan signals in response to the enable level of the first signal CtrL1, such as the first scan signal SN1 to the fourth scan signal SN4, the nineth scan signal SN9 to the twelfth scan signal SN12. The eight primary scan signals from the first and third areas are all output as scan signals to a pixel circuit in the first and third areas to jointly drive the corresponding display partitions to display images. In a current frame, the refresh frequencies of the display partitions controlled by the first area and the third area are same.

Referring to FIG. 3, the (i+1)-th area further includes gating circuits 20. The at least one control signal line 30 further includes a second control signal line 32. The gating circuits 20 in the (i+1)-th area are electrically connected to the second control signal line 32, and the gating circuits 20 in the (i+1)-th area responds to the second signal CtrL2 on the second control signal line 32 to control frequencies of scan signals SN of the gating circuits 20 in the (i+1)-th area. In one embodiment, at least two control signal lines 30 are used to control a conduction or cutoff of gating circuits 20 in the plurality of shift register areas. The gating circuits 20 in the (i+1)-th area are not electrically connected to the first control signal line 31 but are electrically connected to the second control signal line 32. The conduction or cutoff of the gating circuits 20 in the (i+1)-th area are controlled by the second signal CtrL2 on the second control signal line 32. Therefore, even if a voltage jump of the first signal CtrL1 occurs during a driving period corresponding to the (i+1)-th area, a non-enabling level (e.g., low level) following the voltage jump of the first signal CtrL1 will not cut off the scan signals in the (i+1)-th area.

Specifically, referring to FIG. 5, taking i=1 and j=2 as an example, an enable level of the second signal CtrL2 on the second control signal line 32 is a high level. The enable level of the first signal CtrL1 may overlap the enable level of the second signal CtrL2. The first signal CtrL1 and the second signal CtrL2 are independent of each other. In some embodiments, any form of the first signal CtrL1 may be used, and any form of the second signal CtrL2 can be superimposed, so that the refresh frequency combination of the display panel partitions can be increased.

Exemplarily, referring to FIG. 5, the four gating circuits 20 in the second area respectively generate scan signals in response to the second signal CtrL2 on the second control signal line 32, such as the fifth scan signal SN5 through the eighth scan signal SN8.

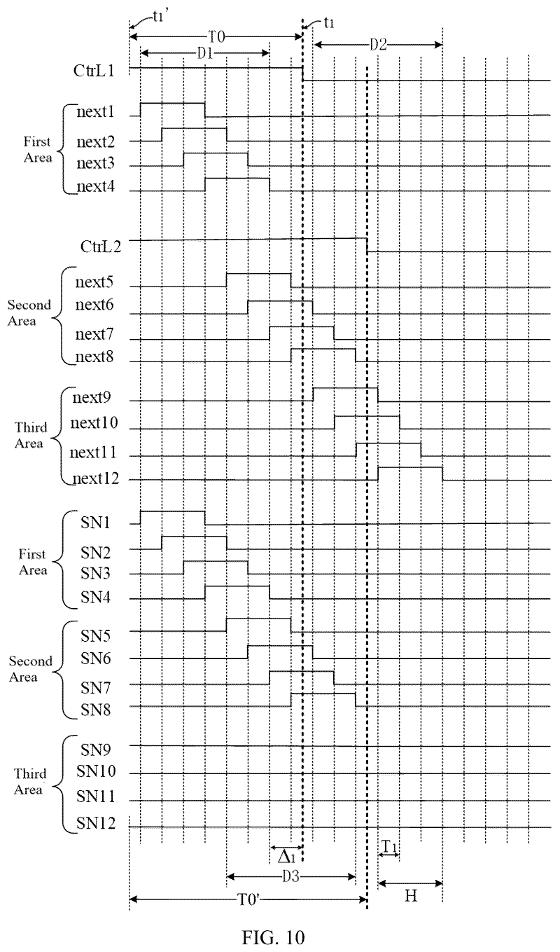

FIG. 10 illustrates a driving timing diagram of another display panel consistent with various embodiments of the present disclosure. Referring to FIG. 10, a duration occupied by a plurality of primary scan signals in the (i+1)-th area (taking i=1 as an example) is a third duration D3. A width TO′ of the enable level of the second signal CtrL2 is greater than the third duration D3.

Specifically, referring to FIG. 10, taking i=1 as an example, in one frame of the display panel, the width TO′ of the enable level of the second signal CtrL2 is controlled to be greater than the third duration D3, and the enable level of the second signal CtrL2 covers the primary scan signal of the (i+1)-th area (e.g., i=1). A voltage jump of the second signal CtrL2 is prevented from occurring during the driving period corresponding to the (i+1)-th area, ensuring that the scan signal in the (i+1)-th area is not cut off.

Exemplarily, referring to FIG. 10, the enable level of the second signal CtrL2 completely covers a primary scan signal in the second area, which is output as a scan signal to a pixel circuit. The frequency of the primary scan signal in the second area is equal to the frequency of the scan signal in the second area. The enable level of the first signal CtrL1 completely covers the primary scan signal in the first area, which is output as a scan signal to the pixel circuit. The frequencies of the primary scan signals are equal to the frequencies of the scan signals in the first area.

The non-enable level of the first signal CtrL1 completely covers the primary scan signal in the third area, the primary scan signal in the third area is not output as a scan signal to a pixel circuit, and a frequency of the primary scan signal in the third area is greater than a frequency of a scan signal in the third area. In one embodiment, a refresh frequency of display partitions controlled by the first area and the second area is greater than a refresh frequency of display partitions controlled by the third area. When the display panel contains many display partitions, a plurality of shift registers is further included before the first area, and another plurality of shift registers are further included after the third area. Functions implemented by the embodiments of the present disclosure include achieving high-frequency refresh in the display partitions controlled by shift registers in and before the second area (e.g., the first area) and enabling low-frequency refresh in the display partitions controlled by the shift registers after the second area (e.g., the third area).

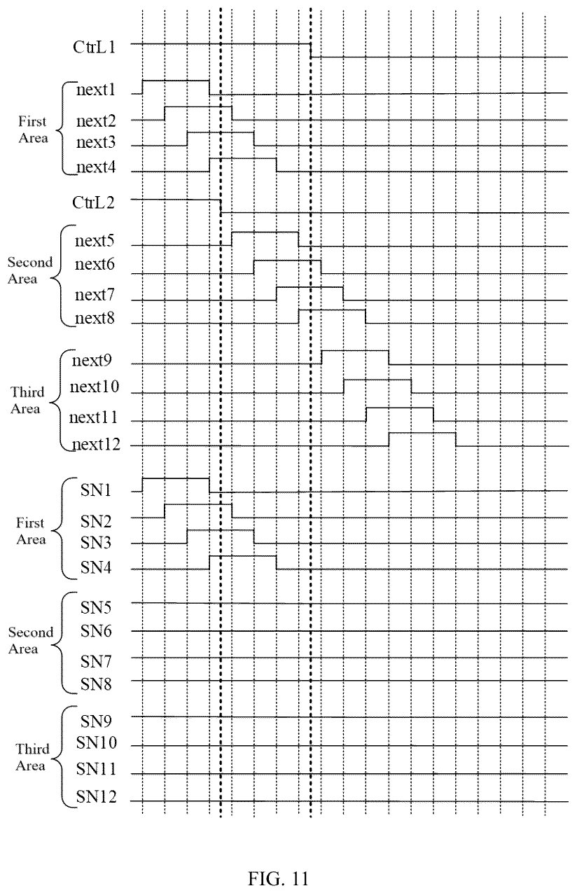

FIG. 11 illustrates a driving timing diagram of another display panel consistent with various embodiments of the present disclosure. Referring to FIG. 11, the non-enable level of the second signal CtrL2 completely covers a primary scan signal in the second area, the primary scan signal in the second area is not output as a scan signal to a pixel circuit, and the frequency of the primary scan signal in the second area is less than the frequency of a scan signal in the second area. The frequencies of the primary scan signals in the first area are equal to frequencies of scan signals in the first area. The frequency of the primary scan signal in the third area is lower than the frequency of the scan signal in the third area. In one embodiment, the refresh frequency of the display partitions controlled by the first area is higher than a refresh frequency of the display partitions controlled by the second and third areas. When the display panel contains many display partitions, a plurality of shift register areas are further included before the first area, and another plurality of shift register areas are further included after the third area. The functions implemented by the embodiments of the present disclosure include achieving high-frequency refresh in the display partitions controlled by shift registers in and before the first area and enabling low-frequency refresh in the display partitions controlled by shift registers after the first area (e.g., the second area and the third area).

Referring to FIG. 3, the i-th area and the (i+1)-th area have a same number of shift registers 10, thereby reducing a difficulty of designing the shift register areas. In other embodiments, the i-th area and the (i+1)-th area may also have different numbers of shift registers 10.

Referring to FIG. 3, in one embodiment, each shift register area may have a same number of shift registers 10 and gating circuits 20. The shift registers 10 and the gating circuits 20 are electrically connected in a one-to-one correspondence. The gating circuit 20 generates a scan signal in response to the first signal CtrL1 or the second signal CtrL2, and controls whether the primary scan signal is output to a pixel circuit as a scan signal. The number of gating circuits 20 in the shift register area affects a setting of a cutoff time of the first signal CtrL1 or the second signal CtrL2 before or after the scan signal of the shift register area, that is, affects a minimum change amount at an intersection of upper and lower halves of a screen that a user can adjust. Exemplarily, the i-th area, the (i+1)-th area and the (i+j)-th area have a same number of shift registers 10. Further, each shift register area in the driving circuit may be arranged to have a same number of shift registers 10. Alternatively, each shift register area in the driving circuit, except a last shift register area, may be arranged to have a same number of shift registers 10.

When the display panel has a plurality of shift register areas 11 with a same or different numbers of shift registers 10, a pulse width H of a scan signal of each shift register area 11 is limited to a shift register area 11 including a least number of shift registers 10.

Based on the above embodiment, and with reference to FIG. 5 and FIG. 10, the plurality of shift register areas 11 include a first shift register area, which has a fewest number of shift registers 10. The first shift register area includes N1 shift registers 10. A time interval between the primary scan signals output by the adjacent shift registers 10 is T1, number of control signal lines 30 is N2, and a pulse width of a scan signal is H. A primary scan signal has a same pulse width as the scan signal, and a pulse width of the primary scan signal is H. The following condition is satisfied: H≤T1×N1×(N2−1), where N1 and N2 are positive integers greater than 1.

The time interval refers to a time difference between two primary scan signals output by two adjacent shift registers 01 in cascade. For example, if the i-th primary scan signal is output by the i-th shift register 10 at time Ti, and the (i+1)-th primary scan signal is output by the (i+1)-th shift register 10 at time Ti+1, the time interval is T=Ti+1−Ti.

One embodiment is explained using the (i+1)-th area which has a fewest number of shift registers 10, as an example. When j=2, the i-th area and the (i+j)-th area are separated by only one shift register area (i.e., the (i+1)-th area). Compared with an interval of a plurality of shift register areas, there is a shorter “gap time” between the i-th area and the (i+j)-th area. A voltage jump (e.g., a falling edge) of the first signal CtrL1 is arranged during the “gap time”, ensuring that scan signals in both the i-th area and the (i+j)-th area are not cut off. The “gap time” is limited by the shift register area 11 with a fewest shift shift registers 10. The longer an “idle time”, the larger a pulse width that can be arranged for a scan signal; the shorter an “idle time”, the smaller a pulse width can be arranged for a scan signal. On the other hand, A pulse width of a scan signal is also affected by number of control signal lines 30. The more control signal lines 30 there are, the more shift register areas exist between the i-th area and the (i+j)-th area. For example, when there are two control signal lines 30, the i-th area is separated from the (i+j)-th area by one shift register area; when there are three control signal lines 30, the i-th area is separated from the (i+j)-th area by two shift register areas; and when there are four control signal lines 30, the i-th area is separated from the (i+j)-th area by three shift register areas. In one embodiment, a pulse width of the scan signal is arranged not to exceed T1×N1×(N2−1), which is conducive to preventing a scan signal being cut off and ensuring that a corresponding primary scan signal is output to a pixel circuit as a scan signal.

Based on the above embodiment, as shown in FIG. 10, H>T1 is arranged to overlap primary scan signals output by adjacent shift registers 10.

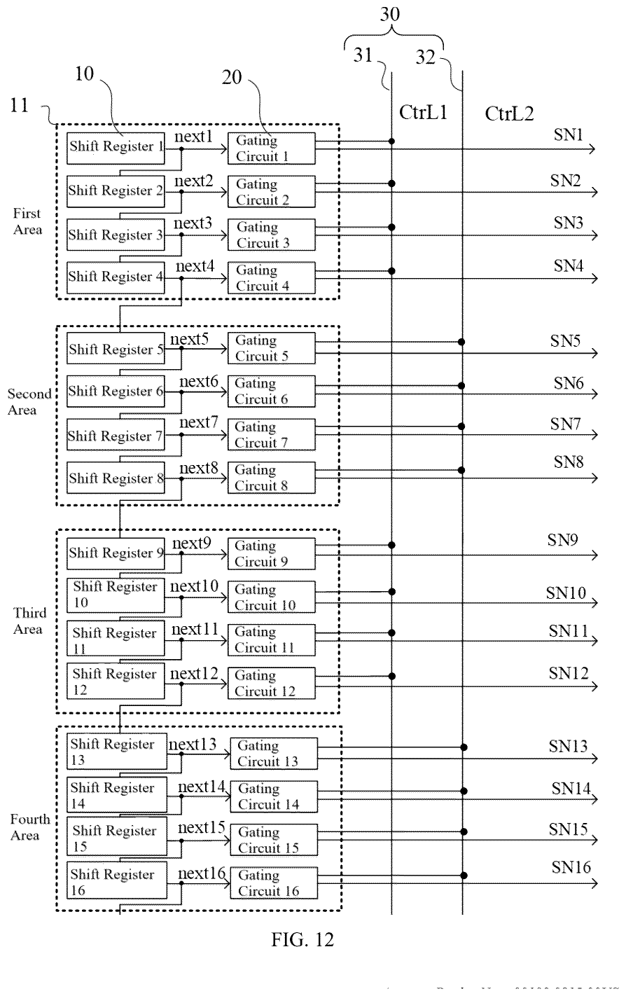

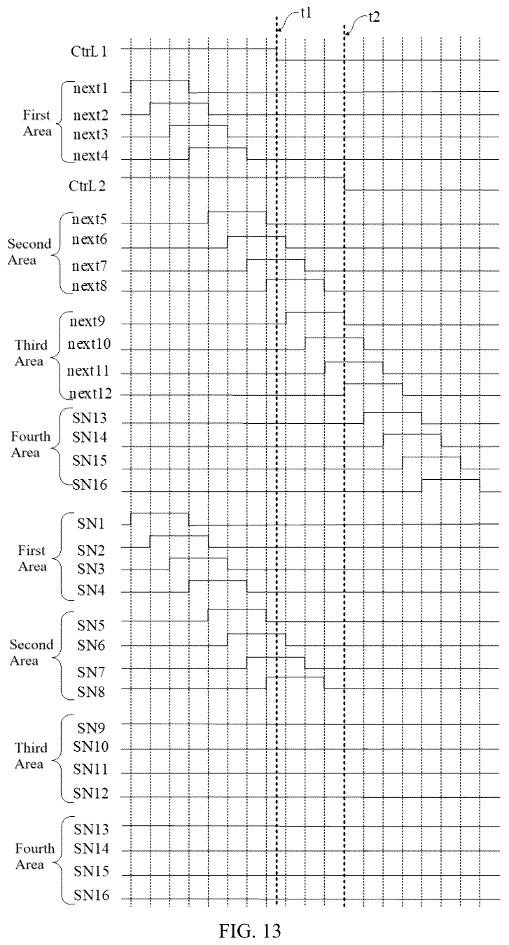

FIG. 12 illustrates a circuit diagram of another display panel consistent with various embodiments of the present disclosure. FIG. 13 illustrates a driving timing diagram of another display panel consistent with various embodiments of the present disclosure.

Referring to FIG. 12, a plurality of shift register areas 11 also include an (i+3)-th area, with a (i+2)-th area located between the (i+1)-th area and the (i+3)-th area. The (i+3)-th area includes a gating circuit 20, which is electrically connected to the second control signal line 32.

Referring to FIGS. 12, i=1 and j=2 is used as an example for illustration. FIG. 12 shows four adjacent shift register areas 11: a first area, a second area, a third area, and a fourth area. Each shift register area includes four shift registers 10 and four gating circuits 20. The four shift registers 10 in the fourth area (illustrated as shift register 13, shift register 14, shift register 15, and shift register 16 in FIG. 12) respectively generate primary scan signals, namely, a thirteenth primary scan signal next13, a fourteenth primary scan signal next14, a fifteenth primary scan signal next15, and a sixteenth primary scan signal next16. The scan signals generated by the four gating circuits 20 in the fourth area (shown as gating circuit 13, gating circuit 14, gating circuit 15, gating circuit 16 in FIG. 12) are a thirteenth scan signal SN13, a fourteenth scan signal SN14, a fifteenth scan signal SN15, and a sixteenth scan signal SN16. Four shift registers 10 and four gating circuits 20 in the first area are shown in FIG. 5, four shift registers 10 and four gating circuits 20 in the third area are shown in FIG. 5, and four shift registers 10 and four gating circuits 20 in the second area are shown in FIG. 5, which will not be described in detail herein.

The first control signal line 31 is electrically connected to the gating circuits 20 in the first area, and to the gating circuits 20 in the third area. The second control signal line 32 is electrically connected to the gating circuits 20 in the second area, and to the gating circuits 20 in the fourth area. That is, gating circuits 20 in odd areas are connected to the first control signal line 31, and gating circuits 20 in even areas are connected to the second control signal line 32. In other embodiments, the gating circuits 20 in the even areas are connected to the first control signal line 31, and the gating circuits 20 in the odd areas are connected to the second control signal line 32.

Referring to FIG. 13, in one frame of the display panel, the enable level of the first signal CtrL1 is high. The enable level of the second signal CtrL2 is high. The first signal CtrL1 activates the gating circuits 20 in the first area, and the frequencies of the primary scan signals are equal to frequencies of scan signals in the first area. The first signal CtrL1 deactivates the gating circuits 20 in the third area, and the frequency of the primary scan signal is greater than the frequency of the scan signal in the third area. The refresh frequency of a pixel circuit driven by the first area is greater than a refresh frequency of a pixel circuit driven by the third area. A voltage jump of the first signal CtrL1 may occur during a driving period corresponding to the second area, and will not cut off the scan signal in the first area. The second signal CtrL2 activates the gating circuits 20 in the second area, the frequencies of the primary scan signals are equal to frequencies of the scan signals in the second area. The second signal CtrL2 deactivates the gating circuits 20 in the fourth area, and the frequency of the primary scan signal in the fourth area is greater than the frequency of the scan signal, and a refresh frequency of a pixel circuit driven by the second area is greater than a refresh frequency of a pixel circuit driven by the fourth area. A voltage jump of the second signal CtrL2 can occur during a driving period corresponding to the third area, and the scan signal in the third area will not be cut off. By adopting odd-even partition control, two adjacent shift register areas 11 are respectively controlled by different control signal lines, which can avoid the scan signal in the adjacent shift register area from being cut off and improve the display effect of the partition frequency control of the display panel. For example, a refresh frequency of a pixel circuit driven by the first area is 120 Hz, a refresh frequency of a pixel circuit driven by the second area is 120 Hz, a refresh frequency of the pixel circuit driven by the third area is 30 Hz, and a refresh frequency of the pixel circuit driven by the fourth area is 30 Hz.

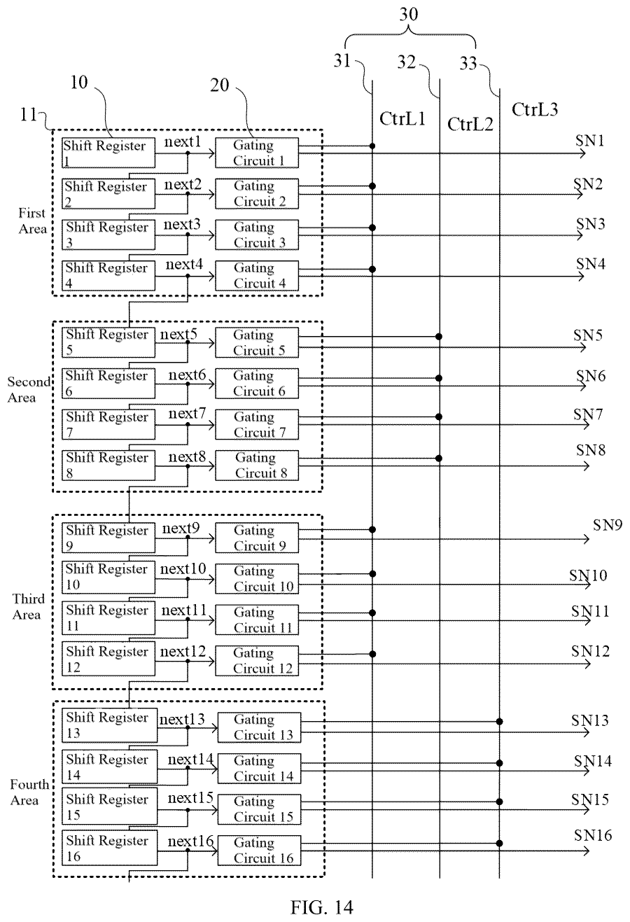

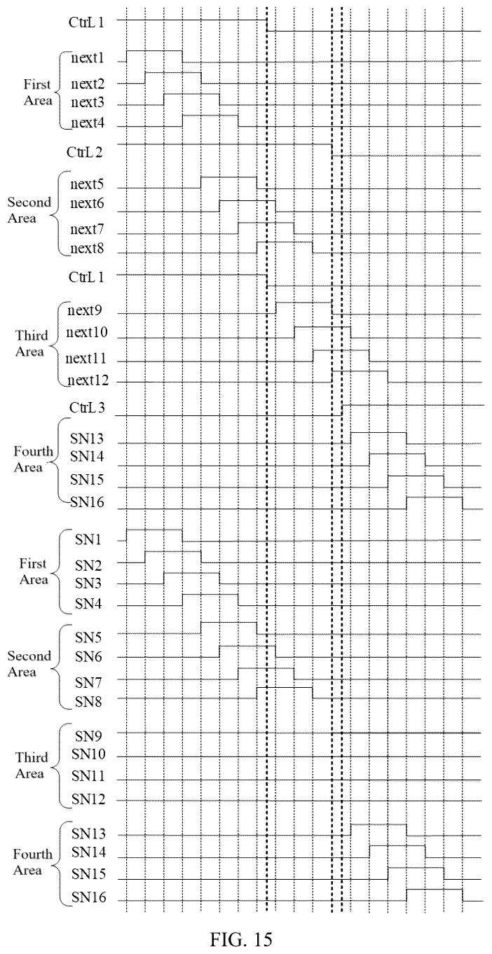

FIG. 14 illustrates a circuit diagram of another display panel consistent with various embodiments of the present disclosure. FIG. 15 illustrates a driving timing diagram of another display panel consistent with various embodiments of the present disclosure.

Referring to FIG. 14, where j=2, the plurality of shift register areas 11 further include the (i+3)-th area with the (i+2)-th area located between the (i+1)-th area and the (i+3)-th area. At least one control signal line further includes a third control signal line 33. Gating circuits 20 in the (i+3)-th area are electrically connected to the third control signal line 33 and controls frequencies of scan signals of the gating circuits 20 in the (i+3)-th area in response to the third signal CtrL3 on the third control signal line 33. In one embodiment, at least three control signal lines 30 may be used to control conductions or cutoffs of the gating circuits 20 in the plurality of shift register areas. The gating circuits 20 in the (i+3)-th area is electrically connected to the third control signal line 33. The conductions or cutoffs of the gating circuits 20 in the (i+3)-th area is controlled by the third signal CtrL3 on the third control signal line 33. Therefore, even if a voltage jump of the second signal CtrL2 occurs during a driving period corresponding to the third signal CtrL3 area, a non-enabling level (e.g., low level) following the voltage jump of the second signal CtrL2 will not cut off the scan signal in the (i+3)-th area.

Specifically, referring to FIG. 14, i=1, j=2 is used as an example for illustration. The enable level of the third signal CtrL3 on the third control signal line 33 is a high level. The enable levels of the first signal CtrL1 and any two or three of the second signal CtrL2 and the third signal CtrL3 may overlap. The first signal CtrL1, the second signal CtrL2, and the third signal CtrL3 are independent of each other. In some embodiments, any form of the first signal CtrL1 may be used, while any form of the second signal CtrL2 and the third signal CtrL3 can be superimposed to increase a refresh frequency combination of the display panel partitions. FIG. 14 shows four adjacent shift register areas 11: a first area, a second area, a third area, and a fourth area, each of which includes four shift registers 10 and four gating circuits 20. The four gating circuits 20 in the fourth area respectively respond to the third signal CtrL3 on the third control signal line 33 to generate scan signals, such as the 13th scan signal SN13 to the 16th scan signal SN16.

Referring to FIG. 15, in one frame of the display panel, the first signal CtrL1 activates the gating circuits 20 in the first area, and the frequency of the primary scan signals are equal to frequencies of scan signals in the first area. The first signal CtrL1 deactivates the gating circuits 20 in the third area, and the frequencies of the primary scan signals are greater than the frequencies of scan signals in the third area. A refresh frequency of a pixel circuit driven by the first area is greater than a refresh frequency of a pixel circuit driven by the third area. The second signal CtrL2 activates gating circuits 20 in the second area and the frequencies of the primary scan signals are equal to frequencies of scan signal in the second area. The third signal CtrL3 controls the gating circuits 20 in the fourth area to be turned off and on and the frequencies of the primary scan signals are equal to frequencies of scan signals in the fourth area. A voltage jump of the first signal CtrL1 can occur during a driving period corresponding to the second area, and the scan signal in the first area will not be cut off. A voltage jump of the second signal CtrL2 can occur during a driving period corresponding to the third area, and the scan signal in the second area will not be cut off. A voltage jump of the third signal CtrL3 can occur during a driving period corresponding to a next shift register area (not shown) in the third area or the fourth area, and the scan signal in the third area will not be cut off, nor will the scan signal in the next shift register area be cut off. The use of three different control signal lines to control different shift register areas 11 respectively helps prevent scan signals in adjacent shift register areas from being cut off, thereby enhancing the display effect of the display panel.

Referring to FIG. 15, by adjusting enable levels of the first signal CtrL1, the second signal CtrL2, and the third signal CtrL3, refresh frequencies of pixel circuits driven by the first, second, third, and fourth areas are controlled to improve a display diversity of the display partitions of the display panel and meet needs of frequency control of different partitions of the display panel. For example, a refresh frequency of a pixel circuit driven by the first area is 120 Hz, a refresh frequency of a pixel circuit driven by the second area is 120 Hz, the refresh frequency of a pixel circuit driven by the third area is 30 Hz, and the refresh frequency of a pixel circuit driven by the fourth area is 120 Hz.

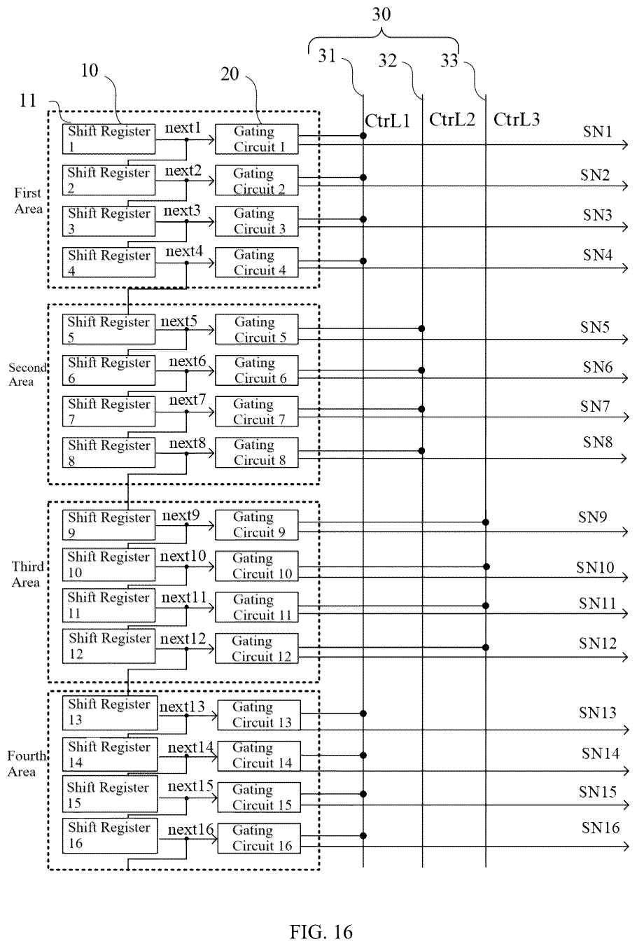

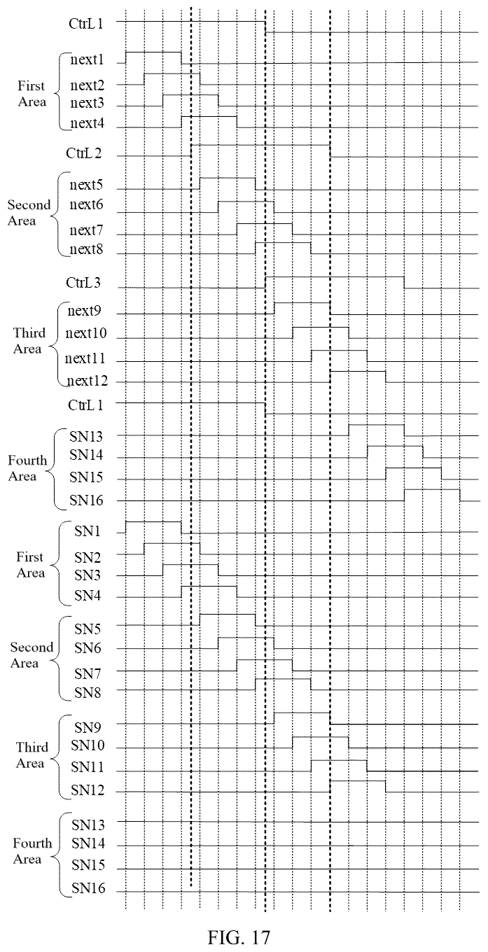

FIG. 16 illustrates a circuit diagram of another display panel consistent with various embodiments of the present disclosure. FIG. 17 illustrates a driving timing diagram of another display panel consistent with various embodiments of the present disclosure.

Referring to FIG. 16, with j=3, the plurality of shift register areas 11 also include the (i+2)-th area located between the (i+1)-th area and the (i+3)-th area. At least one control signal line also includes a third control signal line 33. The gating circuits 20 in the (i+2)-th area is electrically connected to the third control signal line 33 and responds to the third signal CtrL3 on the third control signal line 33 to control the frequency of the scan signal of the gating circuits 20 in the (i+2)-th area.

Referring to FIG. 16, with i=1, j=3 used as an example, FIG. 14 shows four adjacent shift register areas 11: a first area, a second area, a third area, and a fourth area. Each shift register area includes four shift registers 10 and four gating circuits 20.

The first control signal line 31 is electrically connected to the gating circuits 20 in the first area, the first control signal line 31 is electrically connected to the gating circuits 20 in the fourth area, the second control signal line 32 is electrically connected to the gating circuits 20 in the second area, and the third control signal line 33 is electrically connected to the gating circuits 20 in the third area. The three adjacent shift register areas are grouped to enable independent control of the adjacent shift register areas 11 through different control signal lines.

Referring to FIG. 17, in one frame of the display panel, the first signal CtrL1 activates the gating circuits 20 in the first area, and the frequencies of the primary scan signals are equal to the frequencies of the scan signals in the first area. The first signal CtrL1 deactivates the gating circuits 20 in the fourth area, and the frequency of the primary scan signals are greater than the frequencies of scan signals in the fourth area. The refresh frequency of a pixel circuit driven by the first area is greater than the refresh frequency of a pixel circuit driven by the fourth area. The second signal CtrL2 activates the gating circuits 20 in the second area, and the frequencies of the primary scan signals are equal to frequencies of scan signals in the second area. The third signal CtrL3 controls the gating circuit 20 in the third area to be turned on and off, and the frequencies of the primary scan signals are equal to frequencies of scan signals in the third area. A voltage jump of the first signal CtrL1 can occur during a driving period corresponding to the first area, and the scan signal in the first area will not be cut off. A voltage jump of the second signal CtrL2 may occur during a driving period corresponding to the third area, and the scan signal in the second area will not be cut off. A voltage jump of the third signal CtrL3 may occur during a driving period corresponding to the fourth area, and the scan signal in the third area will not be cut off. The scan signal in the adjacent shift register area can be further prevented from being cut off, thereby improving the display effect of the display panel.

In some embodiments, referring to FIG. 3, a cutoff time t1 of the first signal CtrL1 is controlled to occur before the primary scan signal is output by the shift register 10 in the (i+j)-th area (i=1, j=2 in FIG. 3) to ensure that the primary scan signal in the i-th area is output as a scan signal to a pixel circuit, while a primary scan signal in the (i+j)-th area is not output as a scan signal to a pixel circuit.

Referring to FIG. 3, in one frame of the display panel, it is necessary to control the refresh frequencies of the i-th area and the (i+j)-th area to be different, for example, the refresh frequency of the i-th area is 120 Hz, and the refresh frequency of the (i+j)-th area is 60 Hz. Taking a scenario where the refresh frequency of the pixel circuit driven by the i-th area is greater than the refresh frequency of the pixel circuit driven by the (i+j)-th area as an example, an enable level of the first signal CtrL1 overlaps the first scan signal SN1 of the i-th area, to activate the gating circuits 20 in the i-th area. A non-enable level of the first signal CtrL1 overlaps a x-th scan signal SNx in the (i+j)-th area, to deactivate the gating circuits 20 in the (i+j)-th area and cut off a scan signal pulse in the (i+j)-th area. Therefore, the primary scan signal in the (i+j)-th area is used for explanation.

Referring to FIG. 10, taking i=1, j=2 as an example, the cutoff time t1 of the first signal CtrL1 is controlled to occur before the nineth primary scan signal next9 output by the first shift register 10 in the third area, so that the fourth primary scan signal next4 in the first area can is not cut off and can be output to a pixel circuit as a scan signal. The nineth scan signal SN9 in the third area is cut off so that the nineth primary scan signal next9 is not output to the pixel circuit as a scan signal.

Based on the above embodiment, referring to FIG. 3, the cutoff time of the first signal CtrL1 is arranged to occur after scan signals are output by the gating circuits 20 in the i-th area at t1 to ensure that the primary scan signal in the i-th area is output as a scan signal to the pixel circuit.

Referring to FIG. 3, by arranging a cutoff time of the first signal CtrL1 to occur after an n-th scan signal SNn is output by a gating circuit 20 in the i-th area, the cutoff time (e.g., the falling edge) of the first signal CtrL1 will not interrupt the n-th scan signal SNn in the i-th area, thereby ensuring that the primary scan signal in the i-th area is output to a pixel circuit as a scan signal, and the pixel circuit driven by the first area is refreshed.

For example, referring to FIG. 10, where i=1, j=2, the cutoff time t1 of the first signal CtrL1 is controlled to occur after the fourth primary scan signal next4 in the first area, to ensures that the first signa CtrL1 does not cut off the fourth scan signal (SN4).

Based on the above embodiment, and referring to FIG. 10, a start time t1′ of the first signal CtrL1 occurs before the scan signal is output by the gating circuits 20 in the i-th area (i=1 in FIG. 10), so that the start time of the first signal CtrL1 does not occur during a driving period corresponding to the i-th area, so that the scan signal in the i-th area is not cut off, and a corresponding primary scan signal is output to a pixel circuit as a scan signal.

Based on the above embodiment, and referring to FIG. 10, a time interval between primary scan signals output by the adjacent shift registers 10 is T1.

Considering a delay of the first signal CtrL1, if the cutoff time t1 of the first signal CtrL1 coincides with the cutoff time t1 of the scan signal output by the gating circuits 20 in the i-th area, there is a risk of signal competition. In one embodiment, the cutoff time of the enable level of the first signal CtrL1 is arranged to differ from the cutoff time of the scan signal. By controlling a time interval between the cutoff time of the enable level of the first signal CtrL1 and the scan signal, it ensures that once a correct signal control logic of the first signal CtrL is achieved, a next pulse input of the first signal CtrL1 can avoid the risk of signal competition.

In some embodiments, a time interval Δ1 between the cutoff time t1 of the enable level of the first signal CtrL1 and the scan signal output by the gating circuits 20 in the i-th area is greater than or equal to 0.5×T1.

Referring to FIG. 10, the time interval Δ1 between the cutoff time t1 of the enable level of the first signal CtrL1 and the fourth scan signal SN4 output by the gating circuits 20 in the first area is arranged to Δ1≥0.5×T1. Within the time interval Δ1, a voltage jump (e.g., falling edge) of the first signal CtrL1 will not cut off the scan signal in the first area.

In some embodiments, referring to FIG. 9, a time interval 42 between the cutoff time t1 of the enable level of the first signal CtrL1 and the scan signal output by the gating circuits 20 in the (i+j)-th area is greater than or equal to 0.5×T1.

Referring to FIG. 9, with i=1, j=2 as an example for illustration, the time interval Δ2 between the cutoff time t1 of the enable level of the first signal CtrL1 and the 12th scan signal SN12 output by the gating circuits 20 in the third area is arranged to Δ2>0.5×T1. Within the time interval Δ2, a voltage jump (e.g., falling edge) of the first signal CtrL1 will not cut off the scan signal in the third area.

In some embodiments, a time interval between the cutoff time t1 of the enable level of the first signal CtrL1 and the scan signals output by the gating circuits 20 in the i-th area is greater than or equal to 0.5×T1. A time interval between the cutoff time t1 of the enable level of the first signal CtrL1 and the scan signals output by the gating circuits 20 in the (i+j)-th area is greater than or equal to 0.5×T1.

Referring to FIG. 8, it is set that Δ1>0.5×T1, Δ2>0.5×T1. Within the time interval Δ1 and the time interval 42, the scan signal output by the gating circuits 20 in the first area is not cut off, and the scan signal output by the gating circuits 20 in the third area is also not cut off. The primary scan signals of the first area and the third area are both output to pixel circuits as scan signals.

Based on the above embodiments, referring to FIG. 12 and FIG. 13, the enable level of the first signal CtrL1 at least partially overlaps the enable level of the second signal CtrL2. In one embodiment, the enable levels of the second signal CtrL2 and the first signal CtrL1 are both high levels. Pixel circuits driven by the first and second areas can share a same refresh frequency and can be combined into a same display partition. Pixel circuits driven by the third and fourth areas share a same refresh frequency and can be combined into another same display partitions, thereby reducing number of display partitions and enabling diversified partition control to meet display requirements of different display partitions.

Based on the above embodiments, and referring to FIG. 12 and FIG. 13, the cutoff time t2 of the second signal CtrL2 occurs after the primary scan signal output by the shift register 10 in the (i+1)-th area and before the primary scan signal output by the shift register 10 in the (i+3)-th area.

Specifically, referring to FIG. 12, taking i=1, j=2 as an example, the first area, the second area, the third area, and the fourth area are sequentially arranged. The first signal CtrL1 and the second signal CtrL2 both replace a frequency-cutting signal ctrL control in prior technologies. Referring to FIG. 13, the cutoff time t2 of the second signal CtrL2 is arranged before the thirteenth primary scan signal next13 in the fourth area and after the eighth primary scan signal next8 in the second area. The enable level (falling edge) of the second signal CtrL2 will not cut off the scan signal SN8 in the second area but cut off the scan signal of the fourth area. The pixel circuit driven by the second area is refreshed, and the pixel circuit driven by the fourth area is not refreshed.

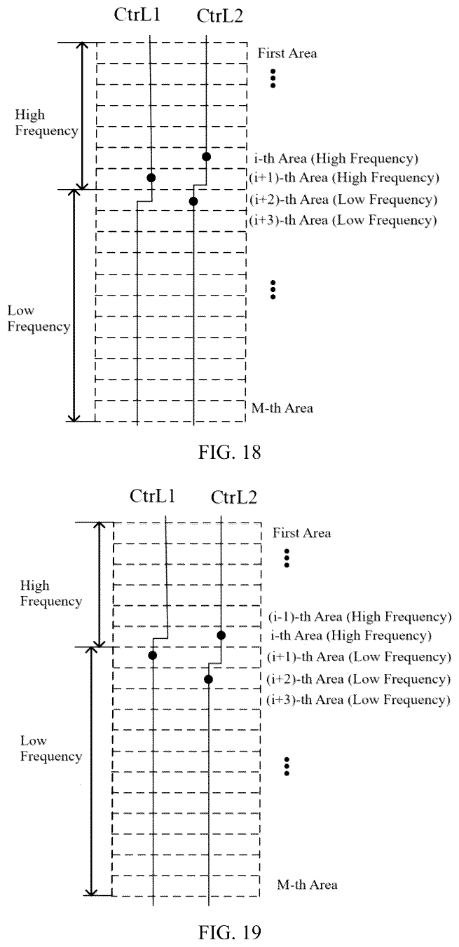

FIG. 18 illustrates a schematic diagram showing varying refresh frequencies across a plurality of shift register areas consistent with various embodiments of the present disclosure.

Referring to FIG. 18, in some embodiments, to achieve the function of splitting the display panel into upper and lower screens, a plurality of shift register areas in cascade can be divided into the first area, . . . , the i-th area, the (i+1)-th area, the (i+2)-th area, the (i+3)-th area, . . . , the M-th area, where i>1, M>i+j.

Referring to FIG. 12, the first signal CtrL1 is used to control the odd areas, and the second signal CtrL2 is used to control the even areas, or the first signal CtrL1 is used to control the even areas, and the second signal CtrL2 is used to control the odd areas. Referring to FIG. 18, after the enable levels of the first signal CtrL1 and the second signal CtrL2 are determined, the pixel circuit driven by the i-th area operates at a high refresh frequency (high frequency), while the pixel circuit driven by the (i+2)-th area operates at a low refresh frequency (low frequency). The pixel circuit driven by the (i+1)-th area also maintains a high refresh frequency. Consequently, the high-frequency areas jointly controlled by the first signal CtrL1 and the second signal CtrL2 encompass the first area through the (i+1)-th area. The low-frequency areas comprise the (i+2)-th area to the M-th area. Therefore, the above configuration effectively enables the function of splitting the display panel into upper and lower screens.

FIG. 19 illustrates a schematic diagram showing another type of varying refresh frequencies across a plurality of shift register areas consistent with various embodiments of the present disclosure.

Referring to FIG. 19, in other embodiments, to achieve the function of splitting the display panel into upper and lower screens, the plurality of shift register areas 11 are divided into the first area . . . , the (i−1)-th area, the i-th area, the (i+1)-th area, the (i+2)-th area, the (i+3)-th area . . . the M-th area.

Specifically, Referring to FIG. 3 and FIG. 12, the gating circuits 20 in the i-th area and the (i+2)-th area are electrically connected to the first control signal line 31, and the gating circuits 20 in the (i−1)-th area, the (i+1)-th area, and the (i+3)-th area are electrically connected to the second control signal line 32. The first signal CtrL1 is used to control the odd areas, and the second signal CtrL2 is used to control the even areas; or the first signal CtrL1 is used to control the even areas, and the second signal CtrL2 is used to control the odd areas. By controlling the cutoff time of the second signal CtrL2 to occur before the primary scan signal output by the shift register 10 in the (i+1)-th area and after the primary scan signal output by the shift register 10 in the i−1th area, the scan signals in the (i+1)-th area and the (i+3)-th area can be cut off, and the pixel circuits driven by the (i+1)-th area and the (i+3)-th area are not refreshed.

Specifically, after the enable levels of the first signal CtrL1 and the second signal CtrL2 are determined, as shown in FIG. 19, when the pixel circuit driven by the i-th area is at a high refresh frequency and the pixel circuit driven by the (i+2)-th area is at a low refresh frequency, the pixel circuit driven by the (i+1)-th area is at a low refresh frequency. Consequently, the high-frequency areas jointly controlled by the first signal CtrL1 and the second signal CtrL2 encompass the first area through the i-th area. The low-frequency areas comprise the (i+1)-th area to the M-th area. Therefore, the above configuration effectively enables the function of splitting the display panel into upper and lower screens.

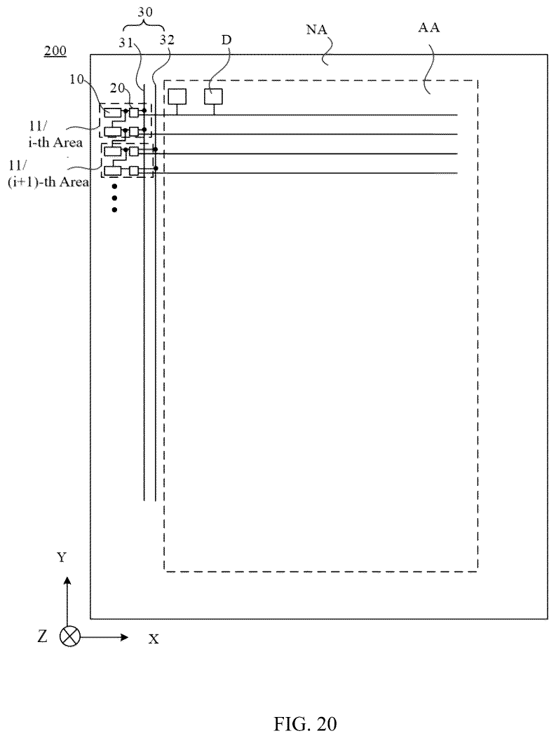

FIG. 20 illustrates a planar view of a display panel consistent with various embodiments of the present disclosure.

Based on the above embodiment, referring to FIG. 20, the display panel 200 includes a display area AA and a non-display area NA. The non-display area NA includes a plurality of shift register areas 11. The first control signal line 31 and the second control signal line 32 are arranged in sequence between the gating circuits 20 and the display area AA.

Specifically, referring to FIG. 20, the display area AA is configured for normal display of images, the non-display area NA at least partially surrounds a border area of the display area AA, the first control signal line 31 and the second control signal line 32 extend along a Y direction in FIG. 20, and are arranged in sequence along a X direction in FIG. 20, and are positioned between the gating circuits 20 in the shift register areas 11 and the display area AA, so as to facilitate electrical connections with the gating circuits 20 arranged in sequence, thereby minimizing an area of the non-display area NA and achieving a narrow border design for the display panel 200.

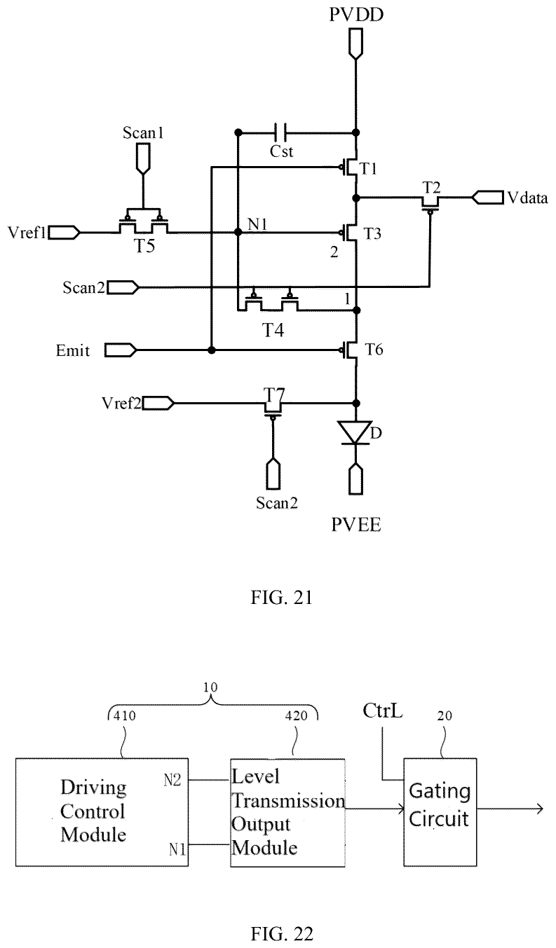

The display area AA also includes a plurality of light emitting elements D. When a gating circuit 20 is turned on, a primary scan signal is output as a scan signal to a pixel circuit, which drives a light emitting element D to either emit light or turn off. For example, FIG. 21 illustrates a structural view of a 7T1C pixel circuit consistent with various embodiments of the present disclosure. Referring to FIG. 21, a 7T1C pixel circuit is used as an example for illustration. In one embodiment, the 7T1C pixel circuit includes 7 transistors and a capacitor (7T1C), which are a light-emitting control transistor T1, a data-writing transistor T2, a driving transistor T3, a threshold compensation transistor T4, an initialization transistor T5, a light-emitting control transistor T6, a reset transistor T7, and a storage capacitor Cst. The 7T1C pixel circuit further includes a first scan signal line Scan1, a second scan signal line Scan2, an enable signal line Emit, a first reference signal line Ref1, a second reference signal line Ref2, a data signal line Data, a first power signal line PVDD, and a common power signal terminal PVEE.

In an initialization stage, the first scan signal line Scan1 controls an on or off state of the initialization transistor T5 of the pixel circuit and resets a gate potential of the driving transistor T3 when the initialization transistor T5 is turned on. In some optional pixel circuit designs, the scan signal Scan 2 can also be multiplexed to control an on or off state of the reset transistor T7 of the pixel circuit and reset an anode potential of the light-emitting element D when the reset transistor T7 is turned on. There is no need to arrange a separate scan signal line for the reset transistor T7. A first initialization signal line Vref1 is used to write an initialization signal to a source of the initialization transistor T5 and to a gate of the driving transistor T3.

In a data writing stage, the second scan signal line Scan2 controls on and off state of the data writing transistor T2 and the threshold compensation transistor T4 in a pixel circuit. When the data writing transistor T2 and the threshold compensation transistor T4 are turned on, the data signal on a data signal line Vdata is written to a gate of the light emitting control transistor T1, and the threshold voltage of the driving transistor T3 is compensated. The second initialization signal line Vref2 is used to write a reset signal to a source of the reset transistor T7, and to an anode of the light emitting element.

In a light-emitting stage, the light-emitting control signal line Emit provides a low-level signal, the light-emitting control transistors T1 and T6 are turned on, and a driving current generated by the driving transistor T3 is transmitted to a light-emitting element to emit light.

It should be noted that a control signal line can be the first scan signal line, which controls the initialization transistor T5 in a pixel circuit to turn on or off, or the second scan signal line Scan2, which controls the data writing transistor T2 and the threshold compensation transistor T4 of the pixel circuit to turn on and off. Scan signals output by the first scan signal line Scan1 and the second scan signal line Scan2 are both utilized for the present disclosure and are included within the protection scope of the present disclosure, which will not be repeated herein.

FIG. 22 illustrates a circuit diagram of another display panel consistent with various embodiments of the present disclosure. Referring to FIG. 22, a shift register 10 may include a driving control module 410 and a level transmission output module 420. The driving control module 410 is configured to control potentials of the first output terminal N1 and the second output terminal N2 of the driving control module 410 according to an input signal of the shift register 10. The level transmission output module 420 is connected to the first output terminal N1 and the second output terminal N2, respectively, and is configured to output a primary scanning signal in response to the potentials of the first output terminal N1 and the second output terminal N2. A scan signal is generated by performing an AND operation on the frequency-cutting signal CtrL and the primary scan signal. The frequency-cutting signal CtrL is configured to control whether the primary scan signal is output as a scan signal. The present disclosure does not focus on a circuit design. Any configuration conforming to current designs of shift registers, gating circuits, and control signal lines remains within the protection scope of the present disclosure.

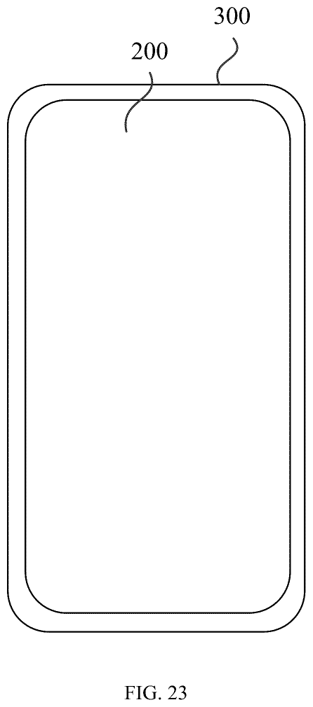

Based on a same inventive concept, one embodiment further provides a display device. FIG. 23 illustrates a schematic diagram of a display device consistent with various embodiments of the present disclosure. As shown in FIG. 23, the display device includes any display panel described in the previous embodiments. Exemplarily, as shown in FIG. 23, the display device 300 includes a display panel. Therefore, the display device benefits from advantages of the display panel described in previous embodiments. Similarities can be understood by referring to previous explanations of the display panel, which will not be repeated herein.

In one embodiment, the display device 300 can be a mobile phone, as shown in FIG. 23, or any electronic product with display functionality, including but not limited to following categories: television, laptop, desktop display, tablet computer, digital camera, smart bracelet, smart glass, car display, industrial control device, medical display screen, touch interactive terminal, or the like.

As disclosed, the display panel and the display device provided by the present disclosure at least realize the following beneficial effects.

In the display panel, a first control signal line is electrically connected to a gating circuit in an i-th area, and to a gating circuit in an (i+j)-th area. An (i+1)-th area is also arranged between the i-th area and the (i+j)-th area. The first control signal line is not electrically connected to the (i+1)-th area. The first control signal line is electrically connected to at least two non-adjacent circuit areas. When the first signal activates the gating circuit in the i-th area and deactivates the gating circuit in the (i+j)-th area, or when the first signal deactivates the gating circuit in the i-th area and activates the gating circuit in the (i+j)-th area, a voltage jump of the first signal can occur during a driving period corresponding to the (i+1)-th area, and the voltage jump of the first signal does not occur during a driving period corresponding to the i-th area and the (i+j)-th area, and scan signals in the i-th area and the (i+j)-th area will not be cut off. An abnormality of the scan signals in the i-th area and the (i+j)-th area is avoided, leading to an improved display effect of the display panel. The embodiments of the present disclosure can not only enable partition frequency control of the display panel, but also prevent the display abnormalities of display partitions, thereby enhancing both the display effect of the display panel and a user experience.

The above are only preferred embodiments of the present disclosure and the technical principles employed. A person skilled in the art will understand that the present disclosure is not limited to the specific embodiments described herein. Various obvious changes, readjustments, combinations and substitutions may be made by a person skilled in the art without departing from the protection scope of the present disclosure. Therefore, although the present disclosure has been described in detail through the above embodiments, the present disclosure is not limited to the above embodiments and may encompass other equivalent embodiments without departing from concepts of the present disclosure. The scope of the present disclosure is determined by the scope of the appended claims.

What is claimed is:

1. A display panel, comprising:
a plurality of shift registers in cascade, for generating primary scan signals, primary scan signals output by adjacent shift registers overlapping;
a plurality of gating circuits, electrically connected to the plurality of shift registers in a one-to-one correspondence, for generating scan signals, a frequency of a scan signal of the scan signals being less than or equal to a frequency of a primary scan signal of the primary scan signals;
control signal lines, including a first control signal line;
a plurality of shift register areas, each of the plurality of shift register areas comprising at least one shift register, the plurality of shift register areas comprising an i-th area, an (i+1)-th area and an (i+j)-th area, the (i+1)-th area being located between the i-th area and the (i+j)-th area, where i is a positive integer, and j is a positive integer greater than 1;
the i-th area, the (i+1)-th area and the (i+j)-th area further including the plurality of gating circuits, gating circuits in the i-th area and the (i+j)-th area being electrically connected to the first control signal line, and in response to a first signal on the first control signal line, frequencies of the scan signals of the gating circuits in the i-th area and the (i+j)-th area being controlled; and
the gating circuits in the (i+1)-th area being not electrically connected to the first control signal line.

2. The display panel according to claim 1, wherein:
a duration occupied by a plurality of the primary scan signals in the i-th area is a first duration, a duration occupied by a plurality of the primary scan signals in the (i+j)-th area is a second duration; and
a width of an enable level of the first signal is greater than a first duration and/or the second duration.

3. The display panel according to claim 2, wherein:
the (i+1)-th area further includes gating circuits of the plurality of gating circuits, and the control signal lines further includes a second control signal line; and
the gating circuits in the (i+1)-th area are electrically connected to the second control signal line and controls frequencies of scan signals of the gating circuits in the (i+1)-th area in response to a second signal on the second control signal line.

4. The display panel according to claim 3, wherein a duration occupied by a plurality of the primary scan signals in the (i+1)-th area is a third duration, and a width of an enable level of the second signal is greater than the third duration.

5. The display panel according to claim 3, wherein the i-th area and the (i+1)-th area have a same number or different numbers of shift registers.

6. The display panel according to claim 2, wherein:
the plurality of shift register areas include a first shift register area, and the first shift register area has a fewest shift registers, including N1-level shift registers; and
a time interval between primary scan signals output by adjacent shift registers is T1, number of the control signal lines is N2, a pulse width of the scan signal is H, satisfies a condition HST1×N1×(N2−1), where N1 and N2 are positive integers greater than 1.

7. The display panel according to claim 6, wherein H>T1.

8. The display panel according to claim 3, wherein:
j=2;
the plurality of shift register areas further includes an (i+3)-th area, with an (i+2)-th area located between the (i+1)-th area and the (i+3)-th area; and
the (i+3)-th area also includes gating circuits of the plurality of gating circuits, and the gating circuits in the (i+3)-th area are electrically connected to the second control signal line.

9. The display panel according to claim 3, wherein:
j=2;
the plurality of shift register areas further includes an (i+3)-th area, and an (i+2)-th area located between the (i+1)-th area and the (i+3)-th area;
the control signal lines also includes a third control signal line; and
the (i+3)-th area includes gating circuits of the plurality of gating circuits, and the gating circuits in the (i+3)-th area are electrically connected to the third control signal line.

10. The display panel according to claim 3, wherein:
j=3;
the plurality of shift register areas further includes an (i+2)-th area located between the (i+1)-th area and an (i+3)-th area;
the control signal line also includes a third control signal line; and
the (i+2)-th area includes gating circuits of the plurality of gating circuits, and the gating circuit in the (i+2)-th area are electrically connected to the third control signal line.

11. The display panel according to claim 1, wherein a cutoff time of the first signal occurs before a primary scan signal output by a shift register of the plurality of shift registers in the (i+j)-th area.

12. The display panel according to claim 11, wherein the cutoff time of the first signal occurs after a scan signal output by a gating circuit of the plurality of gating circuits in the i-th area.

13. The display panel according to claim 12, wherein a start time of the first signal occurs before a scan signal output by the gating circuit in the i-th area.

14. The display panel according to claim 12, wherein:
a time interval between primary scan signals output by adjacent shift registers is T1;
a time interval between the cutoff time of the first signal and the scan signal output by the gating circuit in the i-th area is greater than or equal to 0.5×T1; and/or
a time interval between the cutoff time of the first signal and a scan signal output by a gating circuit of the plurality of gating circuits in the (i+j)-th area is greater than or equal to 0.5×T1.

15. The display panel according to claim 8, wherein an enable level of the first signal at least partially overlaps an enable level of the second signal.

16. The display panel according to claim 15, wherein a cutoff time of the second signal occurs before a primary scan signal output by a shift register of the plurality of shift registers in the (i+3)-th area and occurs after the primary scan signal output by a shift register of the plurality of shift registers in the (i+1)-th area.

17. The display panel according to claim 15, wherein a cutoff time of the second signal is located before the primary scan signal output by a shift register of the plurality of shift registers in the (i+1)-th area, and after the primary scan signal output by a shift register of the plurality of shift registers in the (i−1)-th area, where i is greater than 1.

18. The display panel according to claim 3, further comprising a display area and a non-display area, including the plurality of shift register areas, wherein:
the first control signal line and the second control signal line are arranged in sequence between the plurality of gating circuits and the display area.

19. The display panel according to claim 18, wherein:
the display area further includes a plurality of light emitting elements, when a gating circuit of the plurality of gating circuits is turned on, a primary scan signal is output as a scan signal to a pixel circuit, which drives a light emitting element of the plurality of light emitting elements to either emit light or turn off.

20. A display device comprising a display panel comprising:
a plurality of shift registers in cascade, for generating primary scan signals, primary scan signals output by adjacent shift registers overlapping;
a plurality of gating circuits, electrically connected to the plurality of shift registers in a one-to-one correspondence, for generating scan signals, a frequency of a scan signal of the scan signals being less than or equal to a frequency of a primary scan signal of the primary scan signals;
control signal lines, including a first control signal line;
a plurality of shift register areas, each of the plurality of shift register areas comprising at least one shift register, the plurality of shift register areas comprising an i-th area, an (i+1)-th area and an (i+j)-th area, the (i+1)-th area being located between the i-th area and the (i+j)-th area, where i is a positive integer, and j is a positive integer greater than 1;
the i-th area, the (i+1) area and the (i+j)-th area further including a gating circuit of the plurality of gating circuits, gating circuits in the i-th area and the (i+j)-th area being electrically connected to the first control signal line, and in response to a first signal on the first control signal line, frequencies of the scan signals of the gating circuits in the i-th area and the (i+j)-th area being controlled; and
the gating circuits in the (i+1)-th area being not electrically connected to the first control signal line.
